(19) United States
(12) Patent Application Publication
(10) Pub. No.: US 2025/0157888 A1
(43) Pub. Date: May 15, 2025

(54) ELECTRONIC DEVICE

(71) Applicant: Advanced Semiconductor Engineering, Inc., Kaohsiung (TW)

(72) Inventors: Pao-Nan LEE, Kaohsiung (TW); Yu-Hsun CHANG, Kaohsiung (TW); Nan-Yi WU, Kaohsiung (TW)

(73) Assignee: Advanced Semiconductor Engineering, Inc., Kaohsiung (TW)

(21) Appl. No.: 18/510,493

(22) Filed: Nov. 15, 2023

(51) Int. Cl. H01L 23/48; H01L 23/00; H01L 23/31; H01L 23/538

(52) U.S. Cl. CPC H01L 23/481; H01L 23/3114; H01L 23/5384; H01L 23/5386; H01L 23/562

(57) ABSTRACT

An electronic device is disclosed. The electronic device includes a first electronic component, a second electronic component, and a reinforcing component. The first electronic component is fabricated by a first technology node. The second electronic component is fabricated by a second technology node different from the first technology node. The reinforcing component supports the first electronic component and the second electronic component. The first electronic component has an upper surface facing the reinforcing component and a lower surface configured to receive a first power.

### BACKGROUND

### 1. Field of the Disclosure

The present disclosure generally relates to an electronic device.

### 2. Description of the Related Art

High performance computing (HPC) systems for electronic devices impose challenging demands on power consumption and heat dissipation characteristics of power supply units. Power routing paths for transmitting power signals are usually provided by a system board, over which several dies are mounted. Layout design may be constrained by the need to minimize electromagnetic interference between power signals and non-power signals (e.g., electrical signals), which can limit the ability to miniaturize the system board.

The voltage and power requirements of the dies vary, and the inevitable expansion in the total number and variety of dies has led to a corresponding increase in the number of power routing paths. One approach to providing more power routing paths is to provide power through the backside surface of a die. However, integrating dies with different technology nodes poses a significant challenge in designing power delivery circuits.

### SUMMARY

In some embodiments, an electronic device includes a first electronic component, a second electronic component, and a reinforcing component. The first electronic component is fabricated by a first technology node. The second electronic component is fabricated by a second technology node different from the first technology node. The reinforcing component supports the first electronic component and the second electronic component. The first electronic component has an upper surface facing the reinforcing component and a lower surface configured to receive a first power.

In some embodiments, an electronic device includes a first chiplet, a second chiplet, and a data storage component. The data storage component is configured to communicate with the first chiplet and the second chiplet. The first chiplet has an upper surface facing the data storage component and a lower surface configured to receive a power.

In some embodiments, an electronic device includes a first electronic component, a second electronic component, and a reinforcing component. The first electronic component is supported by the reinforcement component and has a backside power delivery circuit. The second electronic component is supported by the reinforcement component and spaced apart from the first electronic component. An edge of the first electronic component is slanted with respect to an edge of the second electronic component in a bottom view.

### BRIEF DESCRIPTION OF THE DRAWINGS

Aspects of some embodiments of the present disclosure are readily understood from the following detailed description when read with the accompanying figures. It should be noted that various structures may not be drawn to scale, and dimensions of the various structures may be arbitrarily increased or reduced for clarity of discussion.

FIG. 1A illustrates a cross-sectional view of an electronic device according to some embodiments of the present disclosure.

FIG. 1B illustrates a partial enlarged view of the electronic device as shown in FIG. 1A according to some embodiments of the present disclosure.

FIG. 1C illustrates a partial enlarged view of the electronic device as shown in FIG. 1A according to some embodiments of the present disclosure.

FIG. 1D illustrates a layout of the electronic device as shown in FIG. 1A according to some embodiments of the present disclosure.

FIG. 1E illustrates a cross-sectional view of an electronic device according to some embodiments of the present disclosure.

FIG. 2A illustrates a cross-sectional view of an electronic device according to some embodiments of the present disclosure.

FIG. 2B illustrates a partial enlarged view of the electronic device as shown in FIG. 2A according to some embodiments of the present disclosure.

FIG. 2C illustrates a cross-sectional view of an electronic device according to some embodiments of the present disclosure.

FIG. 3A illustrates a cross-sectional view of an electronic device according to some embodiments of the present disclosure.

FIG. 3B illustrates a partial enlarged view of the electronic device as shown in FIG. 3A according to some embodiments of the present disclosure.

FIG. 3C illustrates a cross-sectional view of an electronic device according to some embodiments of the present disclosure.

FIG. 4A, FIG. 4B, FIG. 4C, FIG. 4D, FIG. 4E, FIG. 4F, FIG. 4G, FIG. 4H, FIG. 4I, FIG. 4J, FIG. 4K, FIG. 4L, FIG. 4M, FIG. 4N, FIG. 4O and FIG. 4P illustrate one or more stages of an example of a method for manufacturing an electronic device according to some embodiments of the present disclosure.

FIG. 5A, FIG. 5B, FIG. 5C, FIG. 5D, FIG. 5E, FIG. 5F, FIG. 5G and FIG. 5H illustrate one or more stages of an example of a method for manufacturing an electronic device according to some embodiments of the present disclosure.

FIG. 6A, FIG. 6B, FIG. 6C, FIG. 6D, FIG. 6E, FIG. 6F, FIG. 6G, and FIG. 6H illustrate one or more stages of an example of a method for manufacturing an electronic device according to some embodiments of the present disclosure.

### DETAILED DESCRIPTION

Common reference numerals are used throughout the drawings and the detailed description to indicate the same or similar components. Arrangements of the present disclosure will be readily understood from the following detailed description taken in conjunction with the accompanying drawings.

The following disclosure provides many different arrangements, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include arrangements in which the first and second features are formed or disposed in direct contact and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

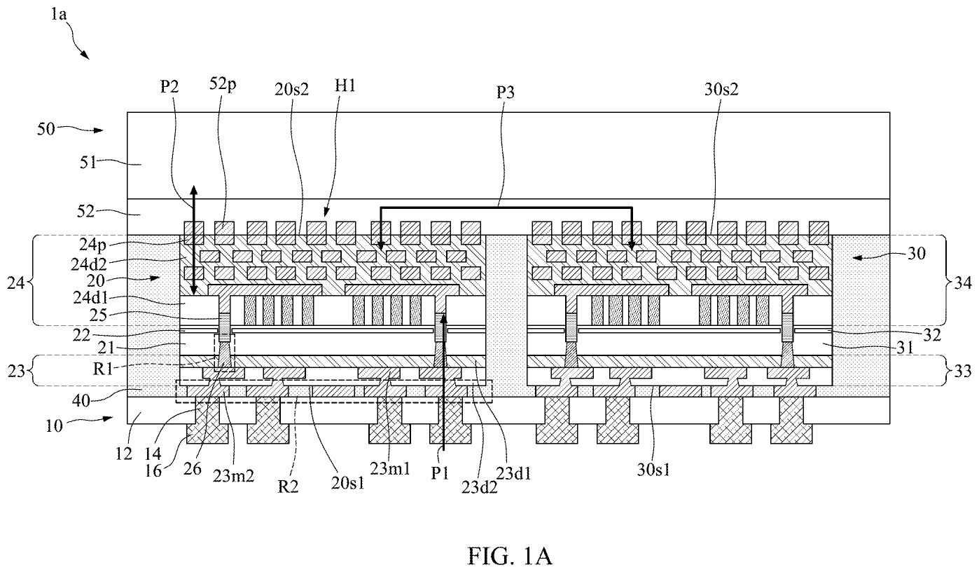

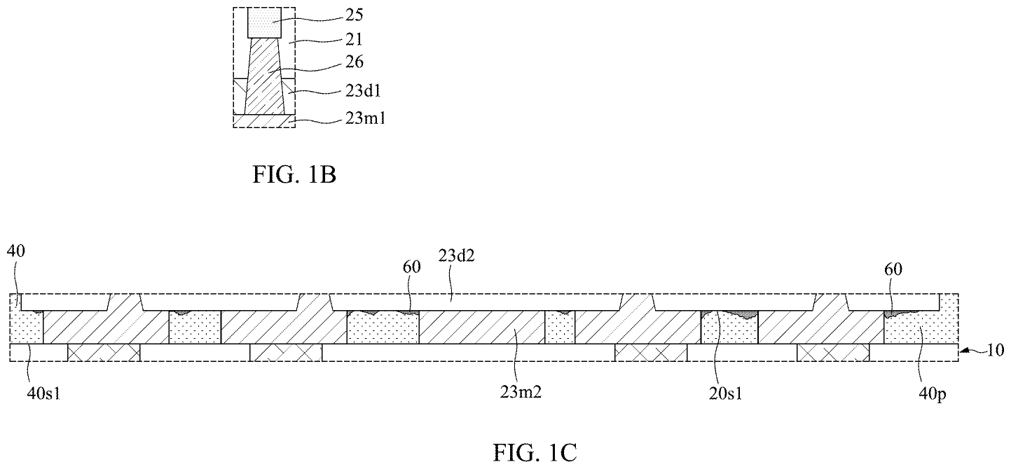

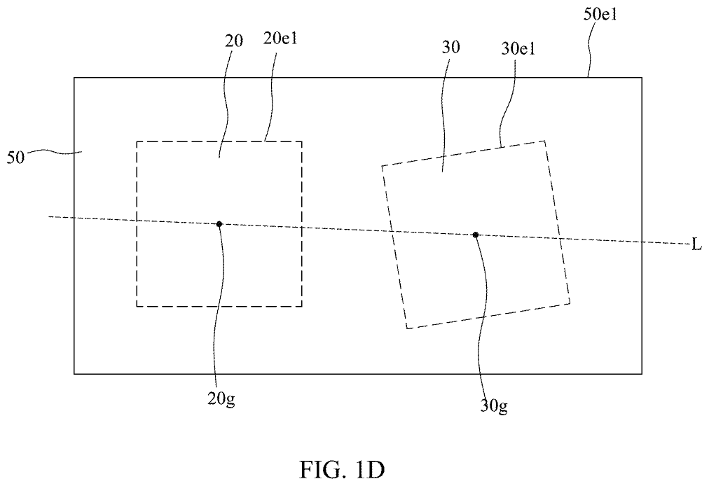

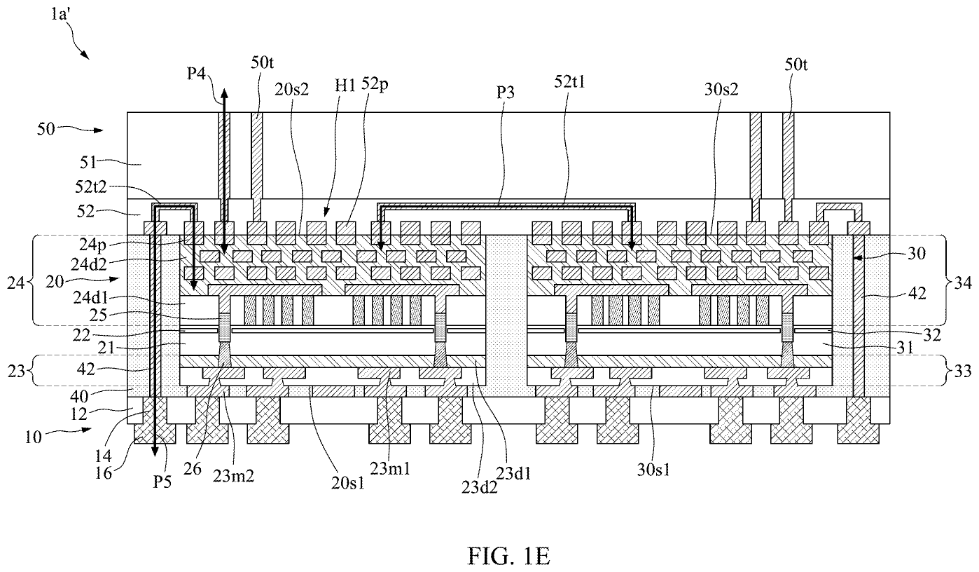

FIG. 1A illustrates a cross-sectional view of an electronic device 1a according to some embodiments of the present disclosure. In some embodiments, the electronic device 1a may include a circuit structure 10, an electronic component 20, an electronic component 30, an encapsulant 40, and a reinforcement component 50.

In some embodiments, the circuit structure 10 may be configured to support the electronic components 20 and 30. The circuit structure 10 may include, for example, a printed circuit board, such as a paper-based copper foil laminate, a composite copper foil laminate, or a polymer-impregnated glass-fiber-based copper foil laminate. The circuit structure 10 may include a redistribution structure, which includes conductive traces and conductive vias embedded within dielectric layers. In some embodiments, the dielectric layer of the circuit structure 10 may include polyimide (PI) or other suitable materials. The circuit structure may include a substrate 12, conductive traces 14, and conductive pads 16.

The substrate 12 may include, for example, polyimide or other suitable materials. The conductive traces 14 may include one or more metal layers and vias. The conductive pad 16 may be disposed under the lower surface of the substrate 12.

The electronic components 20 and 30 may be disposed on or over the circuit structure 10. Each of the electronic components 20 and 30 may be a die. Each of the electronic components 20 and 30 may include an active component that relies on an external power supply to control, output, or modify electrical signals. For example, each of the electronic components 20 and 30 may include a processor, a controller, an input/output (I/O) buffer, etc. In some embodiments, each of the electronic components 20 and 30 may include a chiplet. A chiplet may indicate a circuit area that performs given functionalities with or without another chiplet, and surrounded by a die-to-die space. In some embodiments, the term “chiplet” may be used to refer to a sub-processing unit or sub-processing device within a processing system. Specifically, chiplets may be small modular chips or small integrated circuit (IC) dies with specialized functionality that can be combined to form larger more complex chips, such as a system-on-chip (SoC). A chiplet may be an integrated circuit block designed to work with other similar chiplets within a processing system to execute various processes. A chiplet may also be referred to as a functional block that performs processing operations within a system, such as an SoC. In addition, a chiplet may be a tiny IC that can be configured for a defined or designated set of functionalities. A chiplet may include one or more processing cores to execute system processes in conjunction with other cores of associated chiplets within a system. A chiplet may include input/output functionality to communicate system data with other chiplets and/or other system devices, such as memory, power controllers, I/O controllers and/or interfaces, and the like. Two or more chiplets can be configured or otherwise designed to be combined with other chiplets, for example, on an interposer in or as a unit (e.g., a single package). A set of chiplets can be implemented in a mix-and-match “interlocking tile/brick-like” assembly. Multiple chiplets working together in a single IC may be called a multi-chip module, hybrid IC, 2.5D IC, or any advanced package.

The electronic component 20 may include a surface 20s1 (or a lower surface or a passive surface) and a surface 20s2 (or an upper surface or an active surface) opposite to the surface 20s1. In some embodiments, the electronic component 20 may include a base 21, a circuit region 22, a redistribution structure 23, and a redistribution structure 24. The base 21 (or a base portion) may be a semiconductor substrate, such as a silicon substrate. The base 21 may include a silicon portion or other semiconductor portions.

The circuit region 22 (or logic region) may be disposed within the base 21. The circuit region 22 may include one or more ICs formed within the base 21. The circuit region 22 may be configured to receive power (or a power signal), and generate a signal (or a non-power signal), such as an input/out (I/O) signal or other signals. In some embodiments, the ICs of the circuit region 22 may include fin field-effect transistors (FinFETs), gate-all-around (GAA) transistors, planar transistors, or other transistors.

The redistribution structure 23 (or backside power delivery circuit) may be disposed between the circuit region 22 and the surface 20s1. In some embodiments, the redistribution structure 23 may be configured to receive and/or transmit power, which may include or be composed of direct current (DC), to the circuit region 22. In some embodiments, the redistribution structure 23 may include one or more conductive traces and conductive vias, which function as a part of a power delivery circuit, embedded within one or more dielectric layers. For example, the redistribution structure 23 may include a dielectric layer 23d1, a dielectric layer 23d2, a conductive layer 23m1, a conductive layer 23m2, and conductive vias (not annotated). The dielectric layer 23d1 may be disposed on or below the lower surface of the base 21. The dielectric layer 23d2 may be disposed on or below the dielectric layer 23d1. The conductive layer 23m1 may be disposed below the dielectric layer 23d1 and embedded within the dielectric layer 23d2. The conductive layer 23m2 may be disposed below the dielectric layer 23d2 and exposed by the surface 20s1 of the electronic component 20. The conductive layer 23m2 may function as a terminal of the electronic component 20. In this embodiment, the lower surface of the dielectric layer 23d2 may be regarded as the surface 20s1 of the electronic component 20.

The redistribution structure 24 may be disposed between the circuit region 22 and the surface 20s2 of the electronic component 20. The redistribution structure 24 may be configured to receive and/or transmit a signal (e.g., I/O signal or other signals in communication between different chiplets), which may include or be composed of alternating current (AC). In some embodiments, the redistribution structure 24 may include one or more conductive traces and conductive vias embedded within one or more dielectric layers (e.g., dielectric layer 24d1).

In some embodiments, the electronic component 20 may include a conductive rail 25. The conductive rail 25 may penetrate a portion of the base 21 and the dielectric layer 24d1. The conductive rail 25 may be configured to receive and/or transmit power.

In some embodiments, the electronic component 20 may include a conductive via 26. In some embodiments, the conductive via 26 may include a nanoscale through-silicon via (TSV). The conductive via 26 may penetrate a portion of the base 21 and the dielectric layer 23d1. The conductive via 26 may be electrically connected to the redistribution structure 23 and the conductive rail 25. The conductive via 26 may be configured to receive and/or transmit power.

The electronic component 30 may be disposed adjacent to the electronic component 20. The electronic component 30 may include a surface 30s1 (or a lower surface) and a surface 30s2 (or an upper surface) opposite to the surface 30s1. In some embodiments, the electronic component 30 may include a base 31, a circuit region 32, a redistribution structure 33, and a redistribution structure 34. The base 31 may be a semiconductor substrate, such as a silicon substrate. In some embodiments, the electronic components 20 and 30 may have the same function. In some embodiments, the electronic components 20 and 30 may have different functions.

The circuit region 32 may be disposed within the base 31. The circuit region 32 may include one or more ICs formed within the base 31. The circuit region 32 may be configured to receive power (or a power signal), and generate a signal (or a non-power signal), such as an input/out (I/O) signal or other signals. In some embodiments, the ICs of the circuit region 32 may include fin field-effect transistors (FinFETs), gate-all-around (GAA) transistors, planar transistors, or other transistors.

The redistribution structure 33 may be disposed between the circuit region 32 and the surface 30s1. In some embodiments, the redistribution structure 33 may be configured to receive and/or transmit power, which may include or be composed of DC, to the circuit region 32. In some embodiments, the redistribution structure 33 may include one or more conductive traces and conductive vias embedded within one or more dielectric layers.

The redistribution structure 34 may be disposed between the circuit region 32 and the surface 30s2 of the electronic component 30. The redistribution structure 34 may be configured to receive and/or transmit a signal (e.g., I/O signal or other signals in communication between different chiplets), which may include or be composed of AC. In some embodiments, the redistribution structure 34 may include one or more conductive traces and conductive vias embedded within one or more dielectric layers.

In some embodiments, the electronic components 20 and 30 may be fabricated in the same or different technology nodes, such as 2 nm, 3 nm, 5 nm, 7 nm, 10 nm, 14 nm, 18 nm, 20 nm, 22 nm, 28 nm, 40 nm, 45 nm, 60 nm, 65 nm, 80 nm, 85 nm, or other technology nodes. As used herein, the term “technology node” may indicate a dimension of a semiconductor feature, such as a gate width, channel length, or other suitable features, of an IC.

In some embodiments, the encapsulant 40 may be disposed on or over the circuit structure 10. The encapsulant 40 may encapsulate the electronic components 20 and 30. The encapsulant 40 may include an insulation or dielectric material. For example, the encapsulant 40 may include a molding compound. In some embodiments, the encapsulant 40 may be made of molding material that may include, for example, a Novolac-based resin, an epoxy-based resin, a silicone-based resin, or another suitable encapsulant. Suitable fillers may also be included, such as powdered SiO₂.

In some embodiments, the reinforcement component 50 (or reinforcing component) may be disposed on or over the electronic components 20 and 30. In some embodiments, the reinforcement component 50 may be disposed on or over the encapsulant 40. The reinforcement component 50 may be configured to support the electronic components 20 and 30. The reinforcement component 50 may be configured to communicate with the electronic components 20 and 30. In some embodiments, the reinforcement component 50 may include a data storage component, such as a memory device. The reinforcement component 50 may provide a memory bridge function between the electronic components 20 and 30. In some embodiments, the reinforcement component 50 may further include other ICs, such as CPU, GPU, MPU, MCU, ASIC, and/or FPGA, configured to receive or process the signal from the electronic component 20 and/or electronic component 30. In some embodiments, the reinforcement component 50 may further include passive devices, such as capacitors, which may be configured to regulate power. The reinforcement component 50 may include a substrate 51 and a redistribution structure 52. In some embodiments, the reinforcement component 50 may be a memory chiplet.

The substrate 51 may be a semiconductor substrate, such as a silicon substrate. The redistribution structure 52 may be disposed on or below the substrate 51. The redistribution structure 52 may include one or more conductive traces (not shown) and conductive vias (not shown) embedded within one or more dielectric layers. In some embodiments, the electronic component 20 (or electronic component 30) may be bonded or attached to the reinforcement component 50 by a hybrid-bonding technique. The hybrid-bonding technique may involve a bonding between metal materials (e.g., copper-to-copper bonding) and a bonding between dielectric materials. For example, the electronic device 1a may include a hybrid-bonding structure H1, which includes a bonding between the terminal of the redistribution structure 24 and the terminal of the redistribution structure 52 and a bonding between the dielectric layer of the redistribution structure 24 and the dielectric layer of the redistribution structure 52. In some embodiments, conductive elements 52p of the redistribution structure 52 may be bonded to conductive elements 24p of the redistribution structure 24. The dielectric material of the redistribution structure 52 is bonded to a dielectric layer 24d2 of the redistribution structure 24.

In this embodiment, a backside power delivery technique is applied. For example, the redistribution structure 23 and 33 function as backside power delivery circuits of the electronic components 20 and 30, respectively. In this condition, the base 21 of the electronic component 20 (or the base 31 of the electronic component 30) is thinned to facilitate routing power delivery paths. For example, the base 21 is thinned to facilitate the formation of the conductive via 26. Since the base 21 is thinned, the electronic component 20 has a relatively small rigidity. Such electronic component 20 is delicate, which imposes challenges to package manufacturing processes. In this embodiment, the electronic components 20 and 30 are bonded to or attached to the reinforcement component 50 during the manufacturing processes, which facilitates subsequent manufacturing processes and enhances the process yield.

FIG. 1B illustrates a partial enlarged view of region R1 of the electronic device 1a as shown in FIG. 1A. In some embodiments, the conductive via 26 may have a tapered profile. For example, the conductive via 26 may be tapered toward the reinforcement component 50 as shown in FIG. 1A.

FIG. 1C illustrates a partial enlarged view of region R2 of the electronic device 1a as shown in FIG. 1A. In some embodiments, the encapsulant 40 may have a portion 40p disposed between the surface 20s1 of the electronic component 20 and the circuit structure 10. In some embodiments, the encapsulant 40 may be in contact with the conductive layer 23m2. The portion 40p may function as a mold lock structure that is configured to enhance the adhesion between the circuit structure 10 and the electronic component 20 (or electronic component 30), which thereby reduces the delamination between the electronic component 20 (or electronic component 30) and the circuit structure 10. In some embodiments, the encapsulant 40 has a surface 40s1 (or a lower surface) substantially aligned with the lower surface (not annotated) of the conductive layer 23m2.

In some embodiments, the electronic device 1a may include a residue 60. In some embodiments, the residue 60 may be disposed on or below the surface 20s1 of the electronic component 20. In some embodiments, the residue 60 may be disposed on or below the dielectric layer 23d2. In some embodiments, the residue 60 may be disposed on a lateral surface (not annotated) of the conductive layer 23m2. The residue 60 may be a side-product during manufacturing processes, which will be described in detail later. The residue 60 may include a material of a glue and/or an adhesive. In some embodiments, the residue 60 may be encapsulated by the encapsulant 40.

FIG. 1D illustrates a layout from a top view of the electronic device 1a. The electronic component 20 may have an edge 20e1 (or a side). The electronic component 30 may have an edge 30e1 (or a side). The reinforcement component 50 may have an edge 50e1 (or a side). In some embodiments, the edge 30e1 may be non-parallel or slanted with respect to the edge 20e1. In some embodiments, the edge 30e1 may be non-parallel or slanted with respect to the edge 50e1. In some embodiments, an imaginary line L passing through a geometry center 20g of the electronic component 20 and a geometry center 30g of the electronic component 30 is slanted with respect to the edge 50e1 of the reinforcement component 50. Although FIG. 1D illustrates that the electronic components 20 and 30 have the same dimensions (e.g., surface areas), the electronic components 20 and 30 may have different dimensions in other embodiments.

Referring back to FIG. 1A, the electronic device 1a may include a path P1 (or power transmission path) for transmitting power. The path P1 may pass through the circuit structure 10, redistribution structure 23 (or redistribution structure 33), and surface 20s1 of the electronic component 20 (or surface 30s1 of the electronic component 30). In this embodiment, each of the circuit structure 10 and the redistribution structure 23 (or 33) may collectively function as a part of a power delivery network (PDN) or a part of a power delivery circuit. The circuit structure 10 may be configured to provide both the electronic components 20 and 30 with power. The electronic device 1a may include a path P2 (or non-power transmission path) for transmitting a signal (e.g., I/O signal). The path P2 may pass through surface 20s2 (or 30s2) and the reinforcement component 50. The electronic device 1a may include a path P3 (or non-power transmission path) for transmitting a signal (e.g., a signal in communication between chiplets) between the electronic components 20 and 30. The path P3 may pass through the surface 20s2, the reinforcement component 50, and the surface 30s2.

In a comparative example, an XPU die (or an SoC die) may be configured to integrate multiple functions of ICs. However, the expanding range of functions of an XPU adds to the complexity of integration processes and thus decreases the yield. In order to solve aforementioned problems, an XPU die (or an SoC die) is separated into multiple chiplets. In this embodiment, multiple chiplets, which may be fabricated in different technology nodes, are integrated. Further, said chiplets are configured to receive power from passive surfaces, which thereby increases the number of I/O terminals and enhances the performance of the electronic device 1a.

FIG. 1E illustrates a cross-sectional view of an electronic device 1a′ according to some embodiments of the present disclosure. The electronic device 1a′ is similar to the electronic device 1a as shown in FIG. 1, with differences therebetween as follows.

In some embodiments, the electronic device 1a′ may include conductive elements 42, 50t, 52t1, and 52t2. The conductive element 42 may penetrate or pass through the encapsulant 40. The conductive element 42 may be configured to provide the electronic device 1a′ with an electrical path to an external device (not shown).

In some embodiments, the conductive element 50t may extend between the upper surface (not annotated) of the reinforcement component 50 and the redistribution structure 52. The conductive element 50t may be configured to provide the electronic device 1a′ with an electrical path to an external device (not shown).

In some embodiments, the conductive element 52t1 may be configured to electrically connect the electronic components 20 and 30. The conductive element 52t1 may be a part of the redistribution structure 52. The path P3 may pass through the conductive element 52t1.

In some embodiments, the conductive element 52t2 may be configured to electrically connect the electronic component 20 (or 30) to an external device (not shown). The conductive element 52t2 may be a part of the redistribution structure 52.

In some embodiments, the electronic device 1a may include a path P4 for transmitting power or a signal (I/O signals) between an external device and the electronic component 20 (or 30). The path P4 may pass through the electronic component 20 (or 30) and the conductive element 50t of the reinforcement component 50. In some embodiments, the electronic device 1a may include a path P5 for transmitting power or a signal (I/O signals) between an external device and the electronic component 20 (or 30). The path P5 may pass through the electronic component 20 (or 30), the conductive element 52t2, the conductive element 42, and the circuit structure 10.

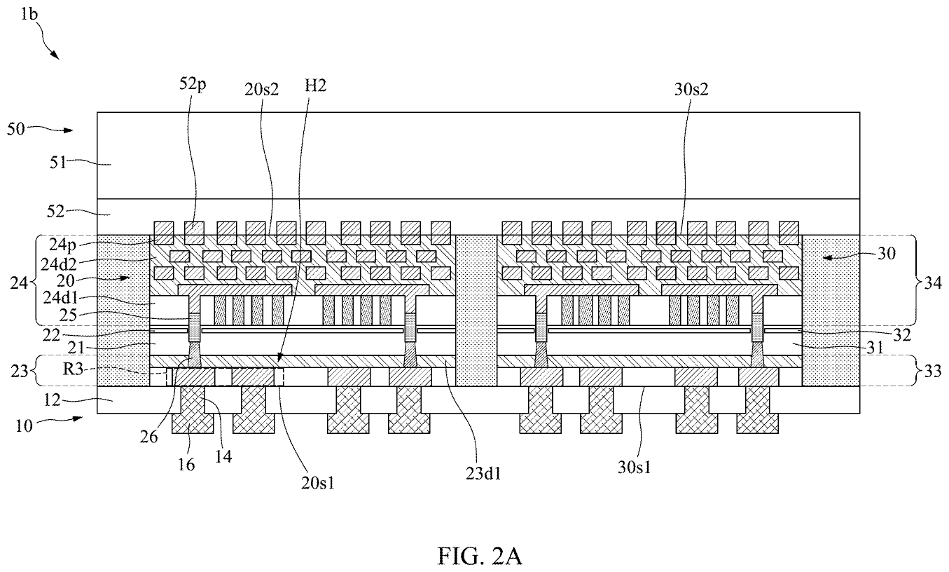

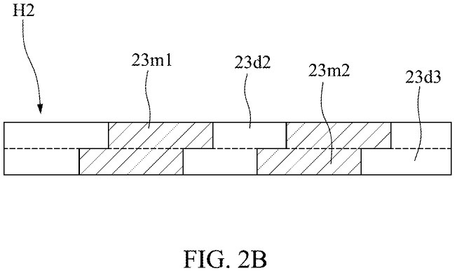

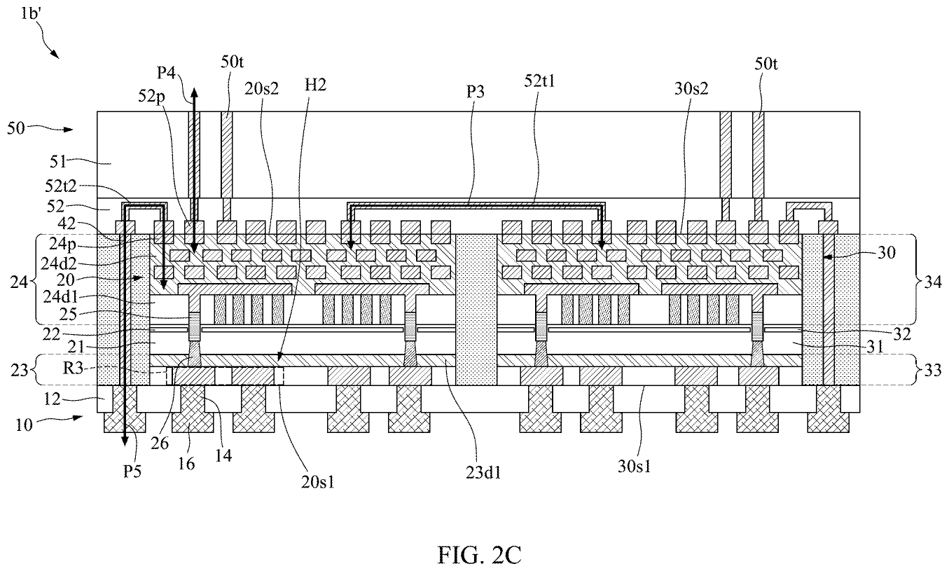

FIG. 2A illustrates a cross-sectional view of an electronic device 1b according to some embodiments of the present disclosure. The electronic device 1b is similar to the electronic device 1a as shown in FIG. 1, with differences therebetween as follows.

In some embodiments, the electronic component 20 may have a hybrid-bonding structure H2 adjacent to the surface 20s1 of the electronic component 20. FIG. 2B illustrates a partial enlarged view of region R3 of the electronic device 1b as shown in FIG. 2A. The hybrid-bonding structure H2 may include a bonding between the dielectric layer 23d2 and a dielectric layer 23d3 and a bonding between the conductive layers 23m1 and 23m2. In some embodiments, the conductive layer 23m1 may be embedded within the dielectric layer 23d2, and the conductive layer 23m2 may be embedded within the dielectric layer 23d3. In some embodiments, the conductive layer 23m1 may be partially misaligned with the conductive layer 23m2. For example, a portion of the lower surface (not annotated) of the conductive layer 23m1 is not covered by the conductive layer 23m2 and is in contact with the dielectric layer 23d3. In some embodiments, the conductive layer 23m2 may be spaced apart from the encapsulant 40, shown in FIG. 2A, by the dielectric layer 23d3.

FIG. 2C illustrates a cross-sectional view of an electronic device 1b′ according to some embodiments of the present disclosure. The electronic device 1b′ is similar to the electronic device 1b as shown in FIG. 2A, with differences therebetween as follows.

In some embodiments, the electronic device 1b′ may include conductive elements 42, 50t, 52t1, and 52t2, which thereby provides the electronic device 1b′ with more power transmission paths or non-power transmission paths.

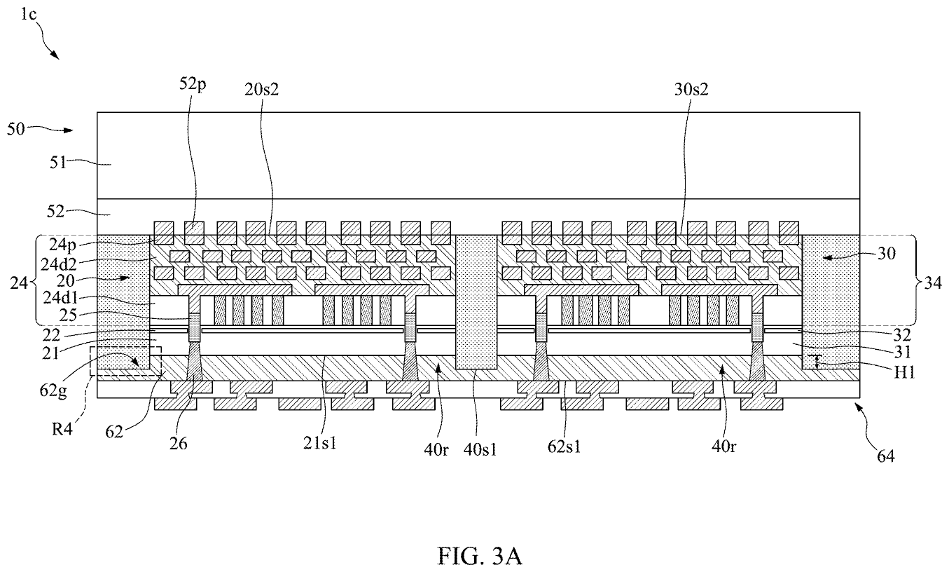

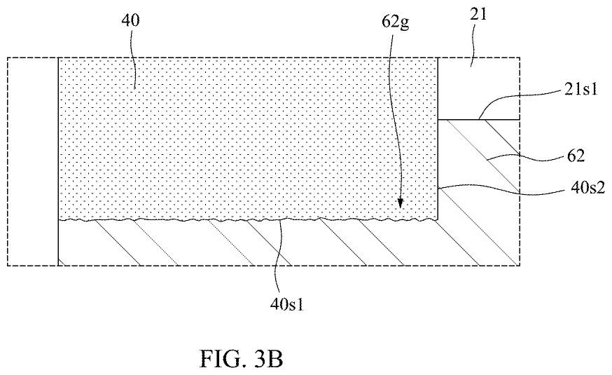

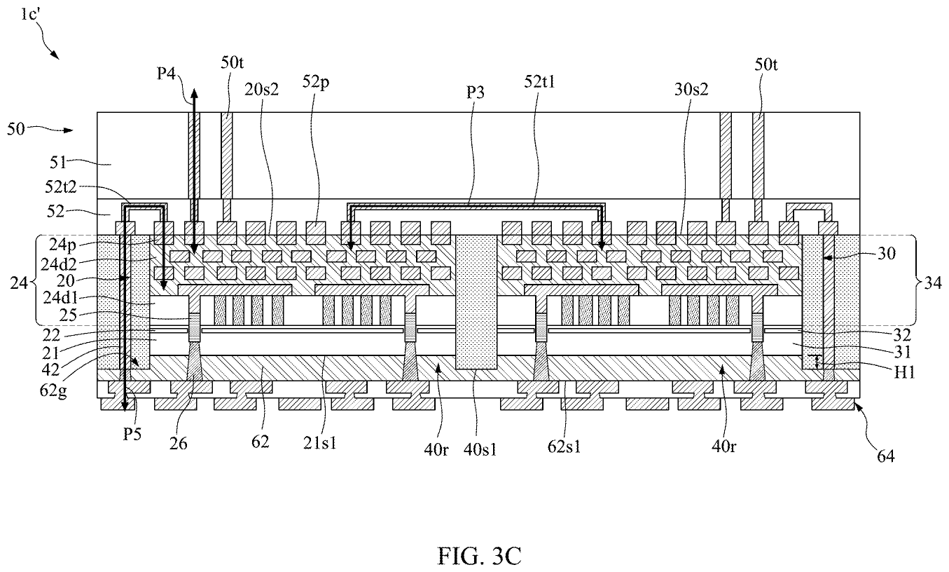

FIG. 3A illustrates a cross-sectional view of an electronic device 1c according to some embodiments of the present disclosure. The electronic device 1c is similar to the electronic device 1a as shown in FIG. 1, with differences therebetween as follows.

In some embodiments, the encapsulant 40 and the base 21 of the electronic component 20 (or the base 31 of the electronic component 30) may define a recess 40r. For example, a surface 40s1 (or a lower surface) of the encapsulant 40 and a surface 21s1 (or a lower surface) of the base 21 may have a height difference H1. In some embodiments, the electronic device 1c may include a planarization layer 62 configured to compensate for the height difference H1, and thus provide a substantially flat surface 62s1 (or a planar surface) to facilitate manufacturing processes. In some embodiments, the planarization layer 62 may cover and be in contact with the surface 40s1 of the encapsulant 40. In some embodiments, the planarization layer 62 may cover and be in contact with the surface 21s1 of the base 21. In some embodiments, the conductive via 26 may penetrate the planarization layer 62.

The electronic device 1c may include a circuit structure 64. The circuit structure 64 may be disposed on or below the planarization layer 62. The circuit structure 64 may include one or more conductive traces and conductive vias embedded within one or more dielectric layers. In this embodiment, the circuit structure 64 may function as a part of the PDN or a part of a power delivery circuit. The circuit structure 64 may include a substrate, conductive traces, and conductive pads.

FIG. 3B illustrates a partial enlarged view of region R4 of the electronic device 1c as shown in FIG. 3A. In some embodiments, the surface 21s1 of the electronic component 20, the surface 40s1 and a surface 40s2 (or a side or a lateral surface) of the encapsulant 40 may collectively define a step 62g. The planarization layer 62 may cover the step 62g. In some embodiments, the roughness of the surface 40s1 may be different from the roughness of the surface 40s2 of the encapsulant 40. In some embodiments, the roughness of the surface 40s1 may be greater than the roughness of the surface 40s2 of the encapsulant 40.

FIG. 3C illustrates a cross-sectional view of an electronic device 1c′ according to some embodiments of the present disclosure. The electronic device 1c′ is similar to the electronic device 1c as shown in FIG. 3A, with differences therebetween as follows.

In some embodiments, the electronic device 1c′ may include conductive elements 42, 50t, 52t1, and 52t2, which thereby provides the electronic device 1c′ with more power transmission paths or non-power transmission paths.

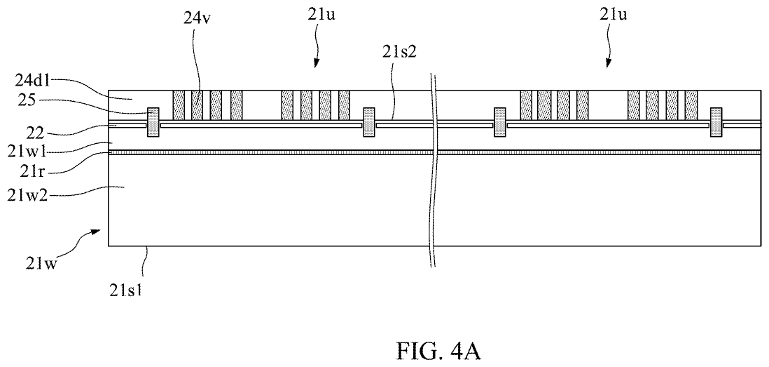

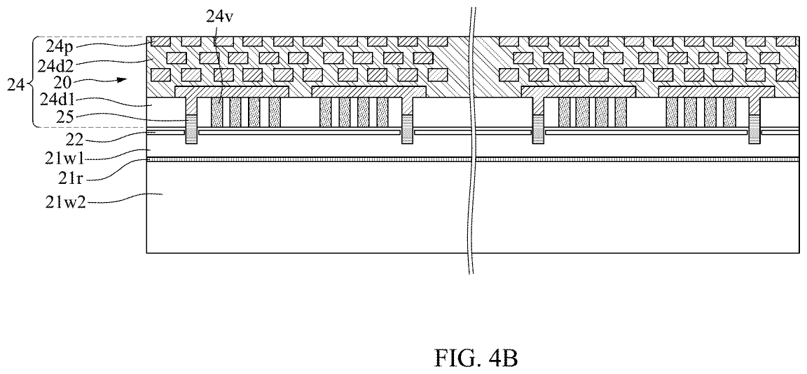

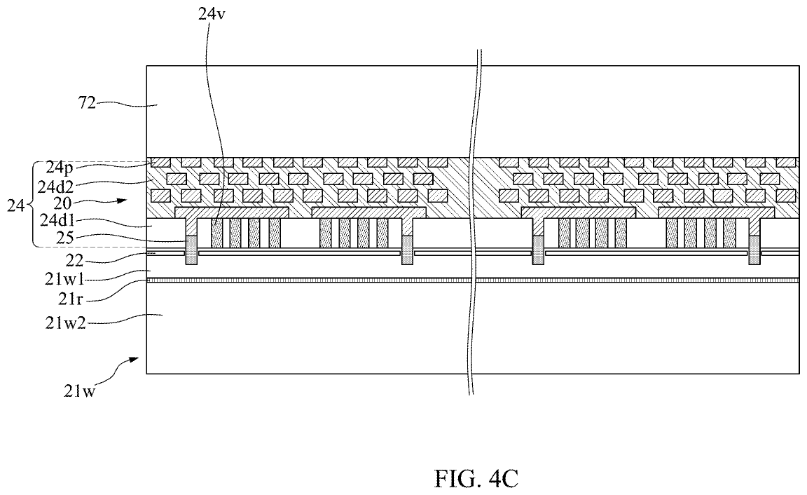

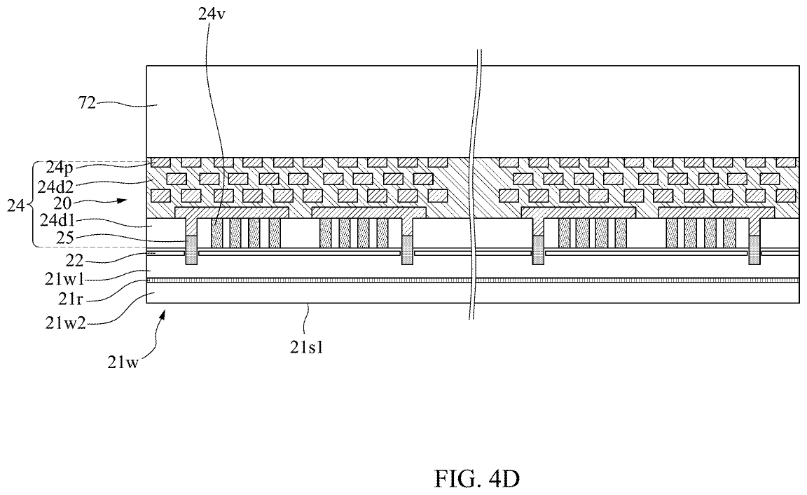

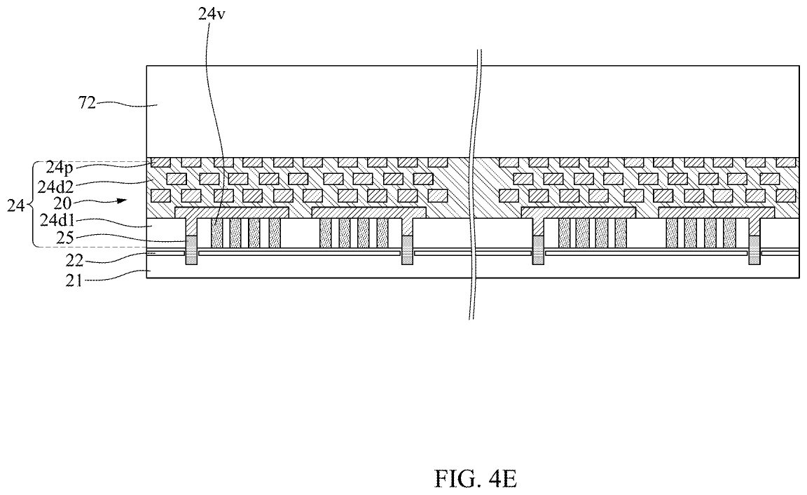

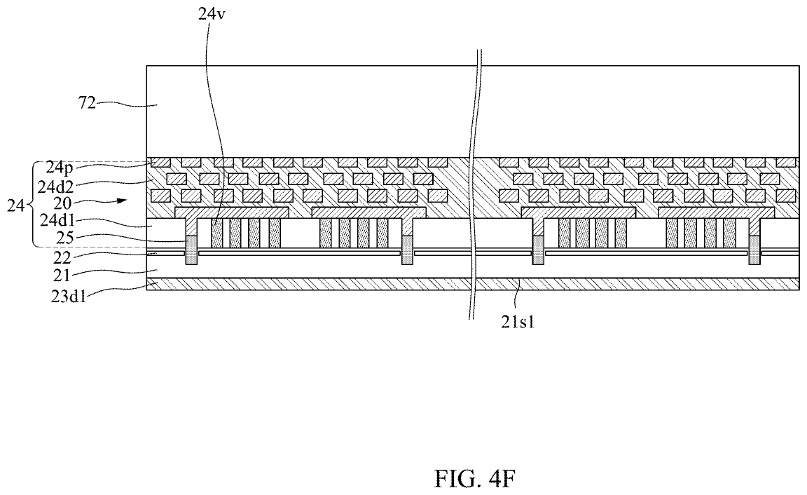

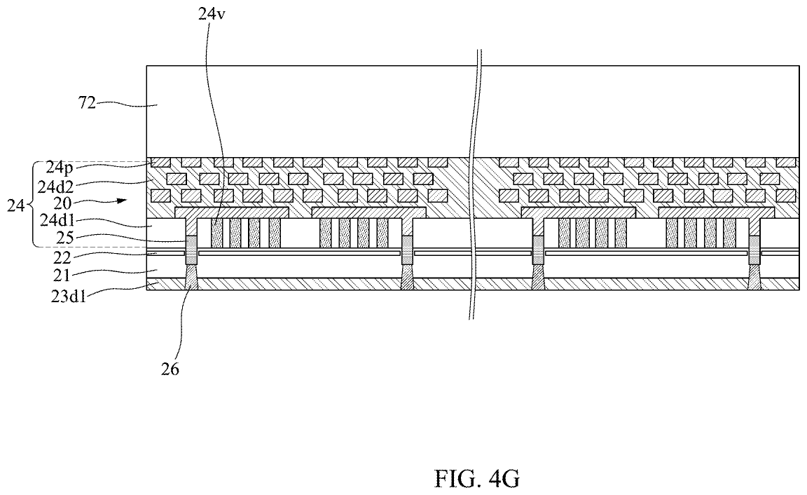

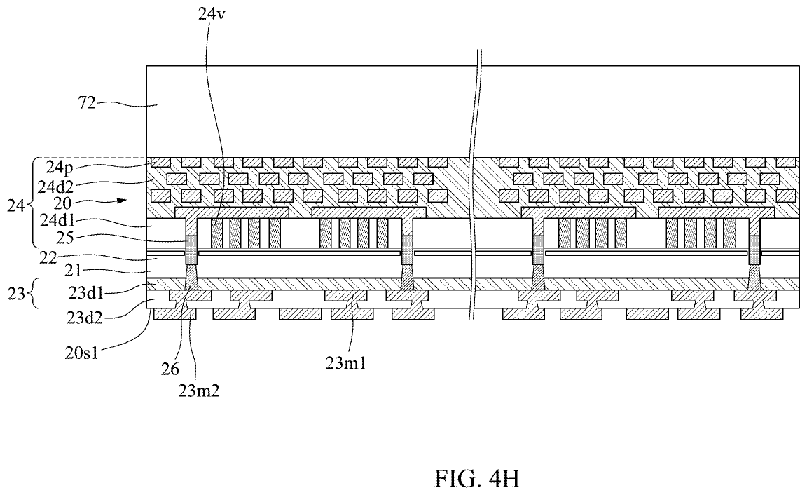

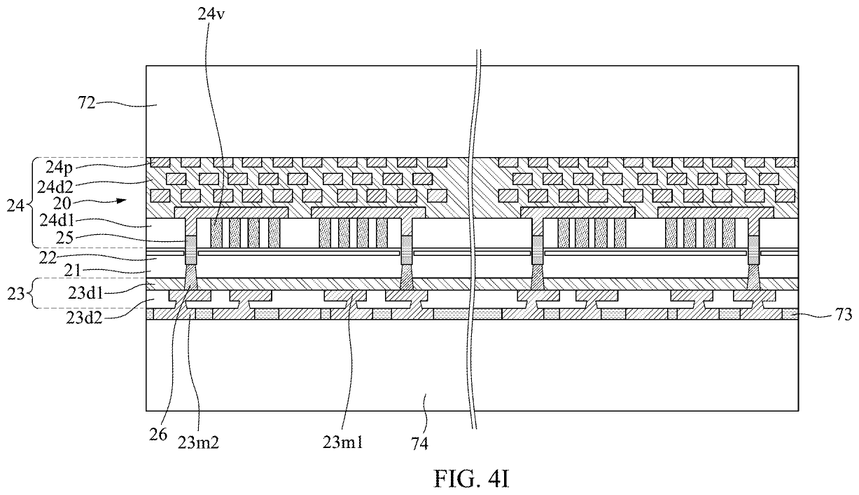

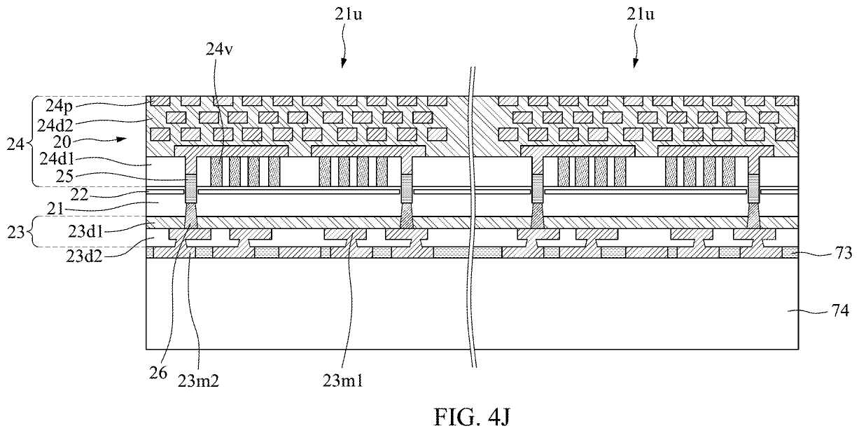

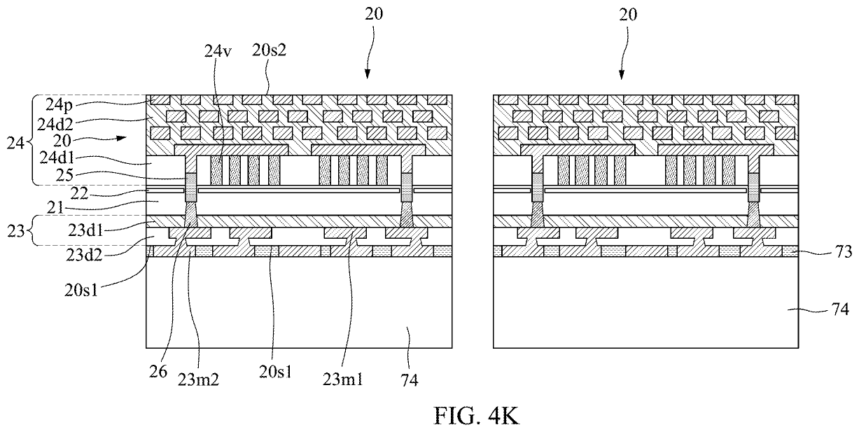

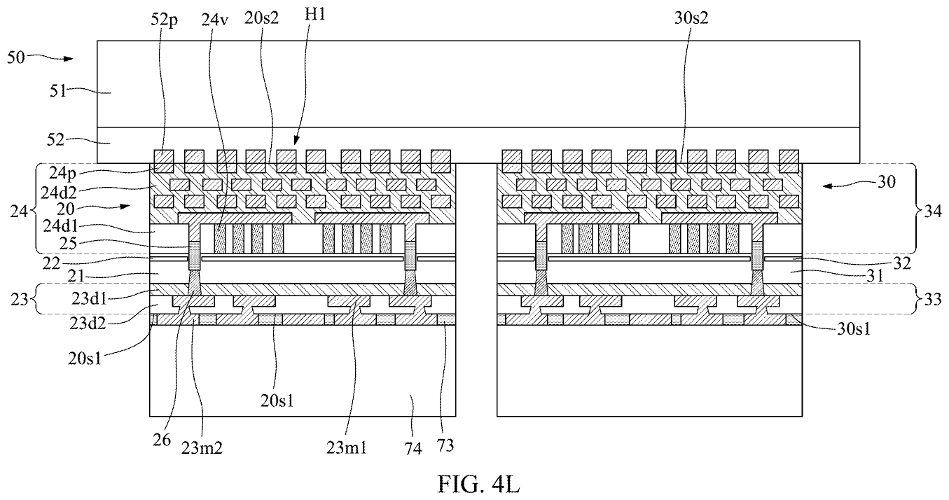

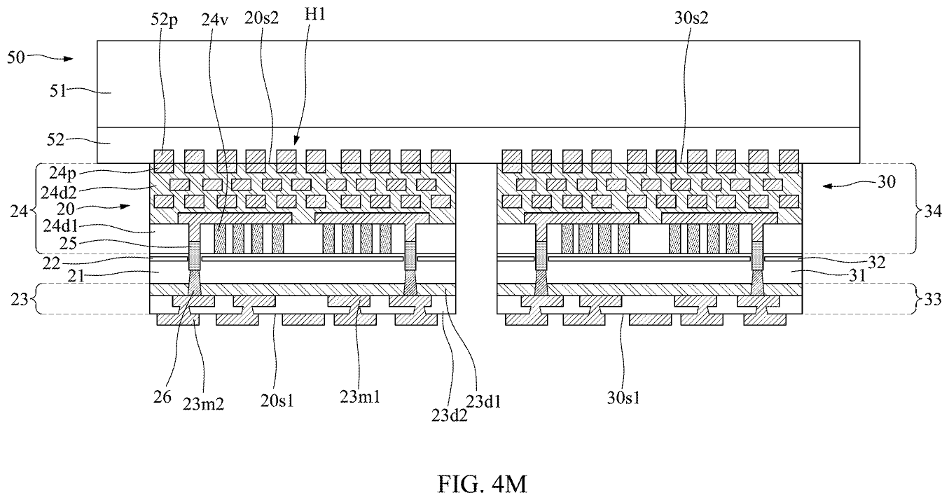

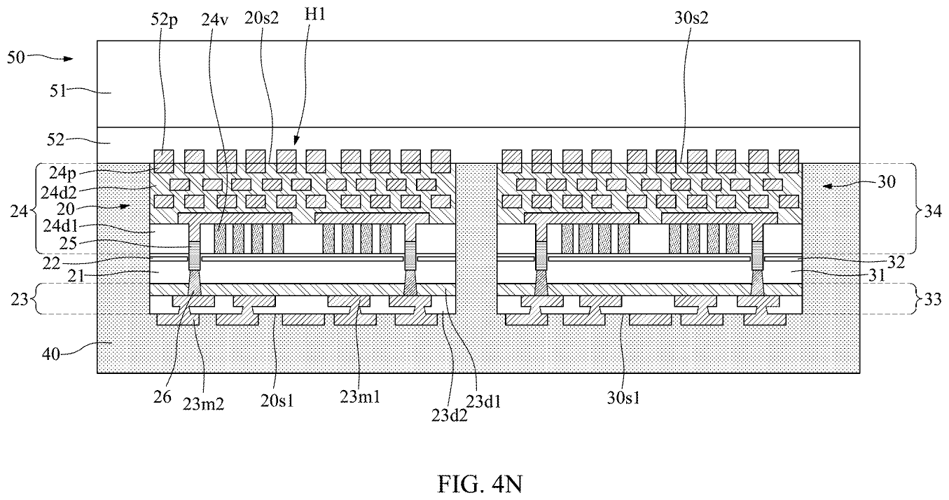

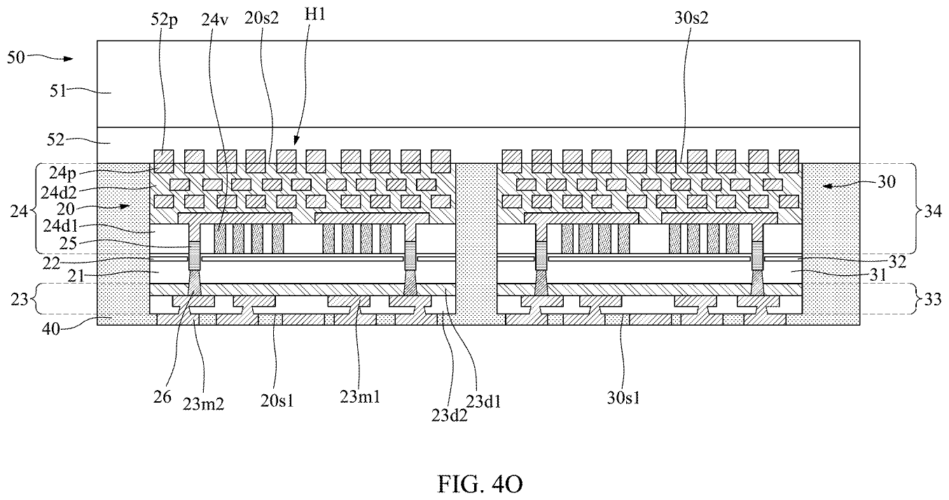

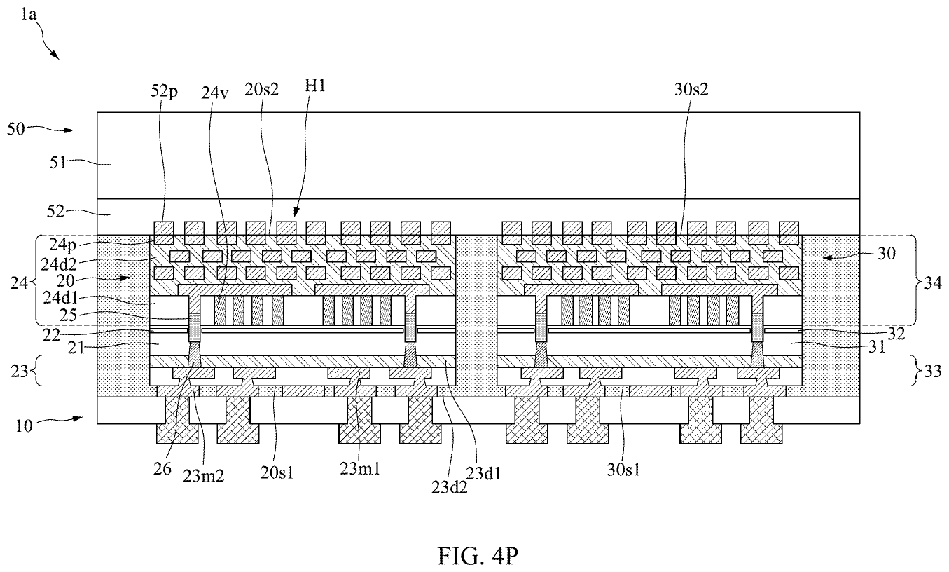

FIG. 4A, FIG. 4B, FIG. 4C, FIG. 4D, FIG. 4E, FIG. 4F, FIG. 4G, FIG. 4H, FIG. 4I, FIG. 4J, FIG. 4K, FIG. 4L, FIG. 4M, FIG. 4N, FIG. 4O and FIG. 4P illustrate one or more stages of an example of a method for manufacturing an electronic device according to some embodiments of the present disclosure.

Referring to FIG. 4A, a wafer 21w may be provided. The wafer 21w may include a plurality of units 21u. Each of the units 21u may form a chiplet after a singulation technique is performed. The wafer 21w may include a portion 21w1, releasing part 21r, and a portion 21w2. The circuit region 22 may be formed within the portion 21w2. The portion 21w1 may be spaced apart from the portion 21w2 by the releasing part 21r. The releasing part 21r may be configured to facilitate removing the portion 21w2 from the portion 21w1. The releasing part 21r may be a part whose structure is destroyed by, for example, an implantation technique. The dielectric layer 24d1 may be formed on a surface 21s2 of the wafer 21w. The conductive rail 25 may be formed adjacent to the surface 21s2. The conductive via 24v may be formed on the surface 21s2 of the wafer and within the dielectric layer 24d1. The conductive via 24v may be configured to transmit power or a signal.

Referring to FIG. 4B, one or more dielectric layers, conductive traces, and/or conductive vias may be formed to produce the redistribution structure 24.

Referring to FIG. 4C, a carrier 72 may be provided. The carrier 72 may be configured to support the wafer 21w and will be removed in subsequent processes. The carrier 72 may include, for example, a silicon carrier, a glass carrier, or other suitable carriers.

Referring to FIG. 4D, the portion 21w2 of the wafer 21w may be ground or polished. As a result, the thickness of the portion 21w2 is reduced.

Referring to FIG. 4E, the releasing part 21r and the portion 21w2 may be removed, and the remaining portion 21w1 defines a base 21.

Referring to FIG. 4F, a dielectric layer 23d1 may be formed on or below the surface 21s1 of the base 21. The dielectric layer 23d1 may be formed by, for example, a coating technique or other suitable techniques.

Referring to FIG. 4G, a conductive via 26 may be formed. The conductive via 26 may penetrate the dielectric layer 23d1 and a portion of the base 21.

Referring to FIG. 4H, a conductive layer 23m1, a dielectric layer 23d2, and a conductive layer 23m2 may be formed to define a redistribution structure 23 below the base 21.

Referring to FIG. 4I, a carrier 74 may be provided. The carrier 74 may be configured to support the base 21 and will be removed in subsequent processes. The carrier 74 may include, for example, a silicon carrier, a glass carrier, or other suitable carriers. The redistribution structure 23 may be attached to the carrier 74 by an adhesive 73. The adhesive 73 may fill the space between the dielectric layer 23d2 and the carrier 74.

Referring to FIG. 4J, the carrier 72 may be removed so that the redistribution structure 24 may be exposed.

Referring to FIG. 4K, the units 21u may be separated to produce multiple electronic components 20. Further, the carrier 74 may be sawed and then separated into multiple segments.

Referring to FIG. 4L, an electronic component 30 and a reinforcement component 50 may be provided. The processes of singulation of the electronic component 30 may be the same as or similar to those described in FIG. 4A to FIG. 4K. The reinforcement component 50 may be bonded or attached to the redistribution structure 24 by, for example, a hybrid-bonding technique or other suitable techniques. For example, the conductive elements 52p of the redistribution structure 52 may be bonded to conductive elements 24p of the redistribution structure 24, and the dielectric material of the redistribution structure 52 may be bonded to the dielectric layer 24d2 of the redistribution structure 24. Similarly, the reinforcement component 50 may be bonded or attached to the electronic component 30 by, for example, a hybrid-bonding technique or other suitable techniques. In some embodiments, the bonding between the redistribution structure 52 and the redistribution structure 24 may involve a copper to copper bonding. Since the electronic components 20 and 30 are attached to the reinforcement component 50 individually, the edges of the electronic components 20 and 30 may be slightly slanted from inaccuracies in the manufacturing equipment.

Referring to FIG. 4M, the adhesive 73 and the carrier 74 may be removed from the electronic component 20. The remaining adhesive 73 may form a residue on the dielectric layer 23d2, such as the residue 60 as shown in FIG. 1C.

Referring to FIG. 4N, an encapsulant 40 may be formed. The encapsulant 40 may encapsulate the electronic components 20 and 30. The encapsulant 40 may cover the surface 20s1 of the electronic component 20 and the surface 30s1 of the electronic component 30.

Referring to FIG. 4O, the encapsulant 40 may be ground. The conductive layer 23m2 may be exposed by the encapsulant 40.

Referring to FIG. 4P, a circuit structure 10 may be formed on or below the redistribution structure 23. As a result, an electronic device (e.g., the electronic device 1a as shown in FIG. 1A) may be produced. In this embodiment, the processes may be performed with a greater yield.

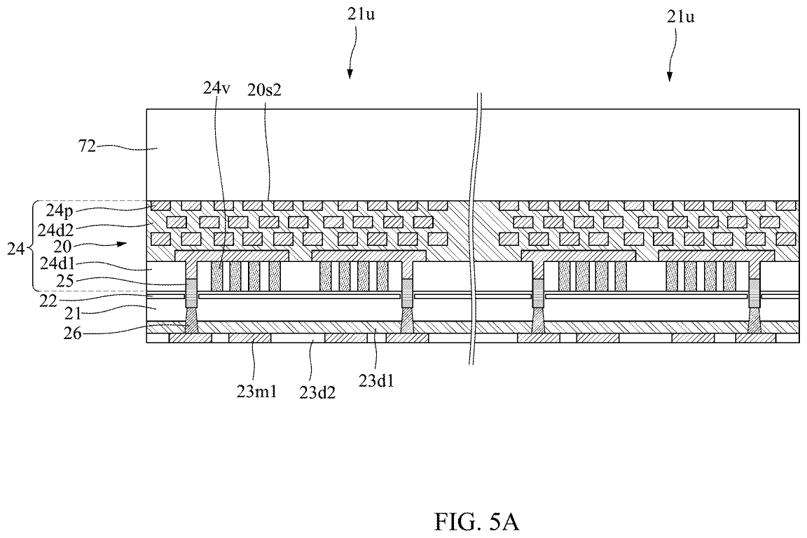

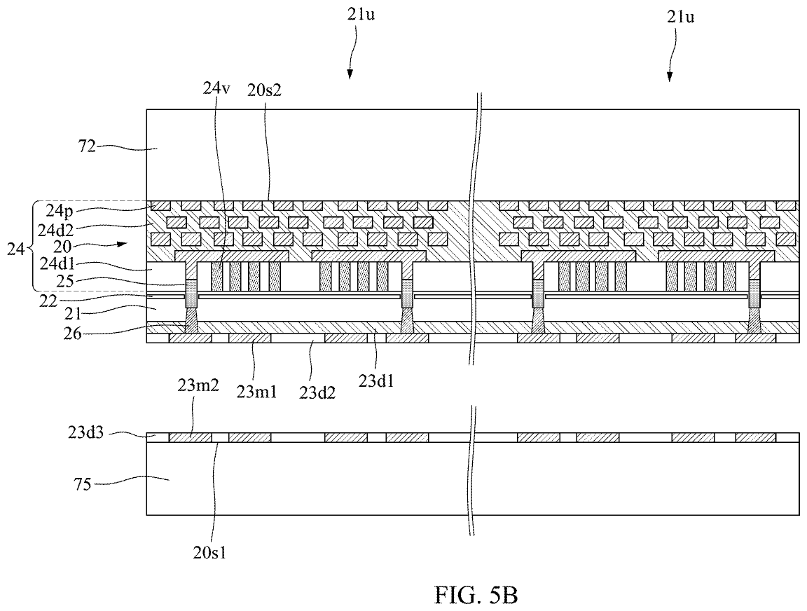

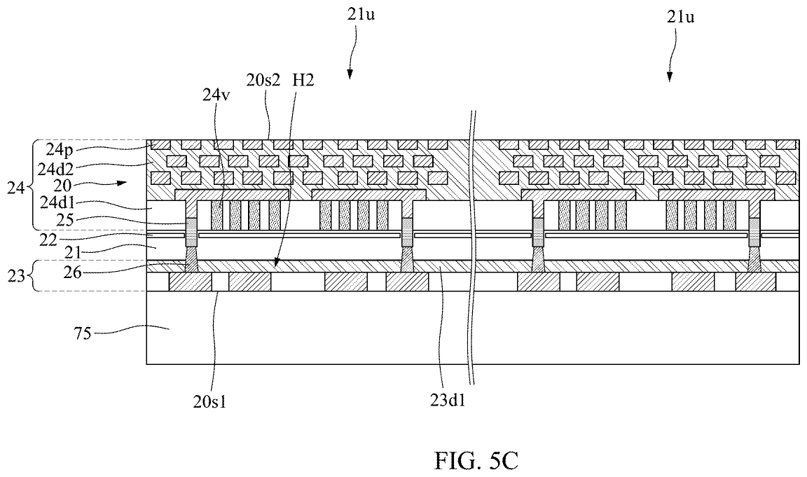

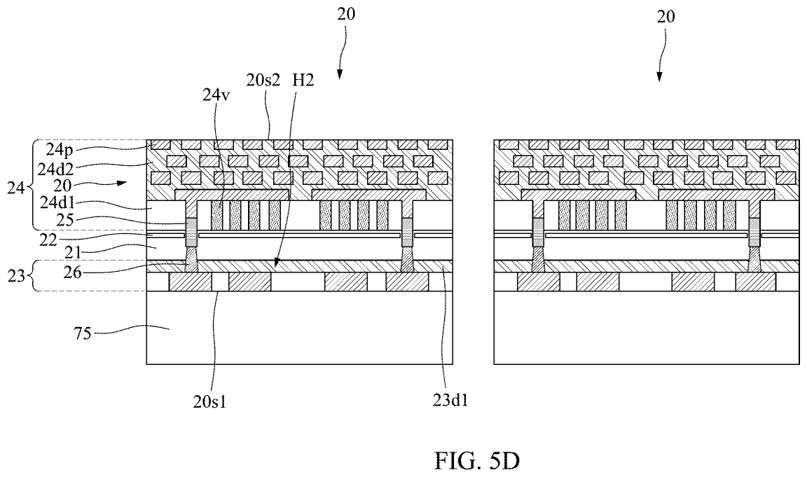

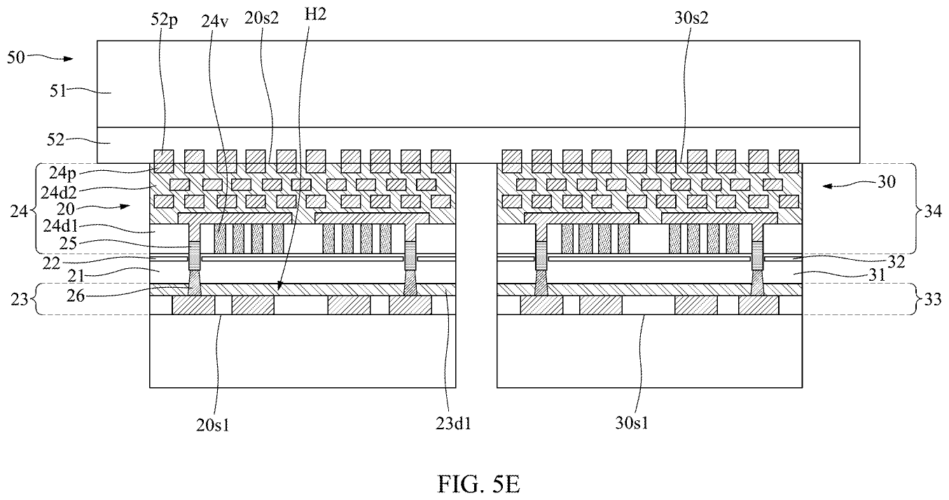

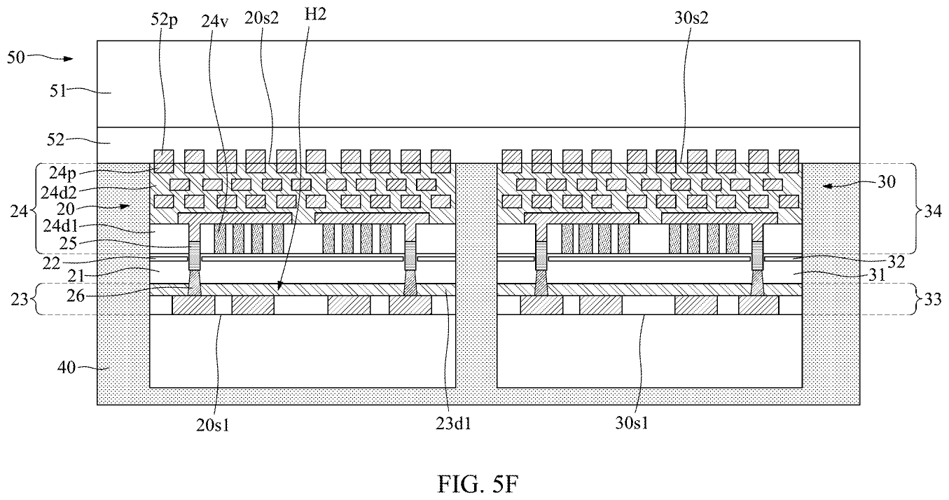

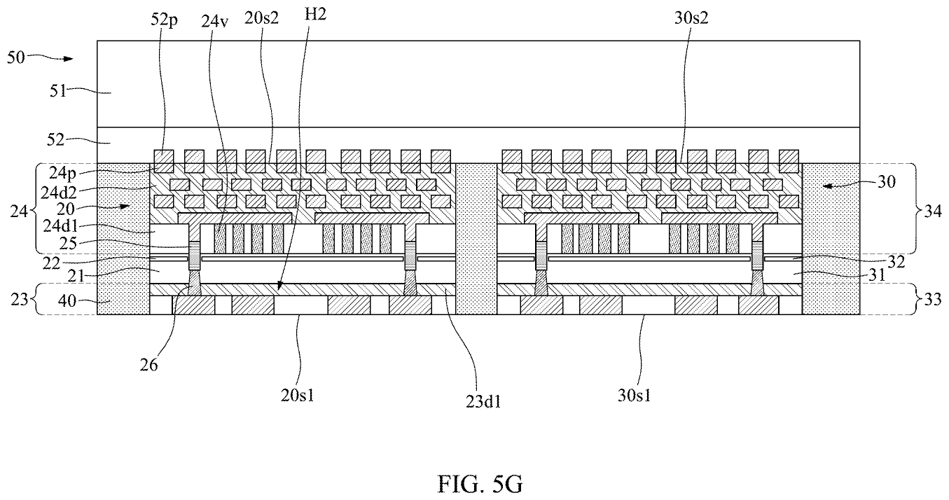

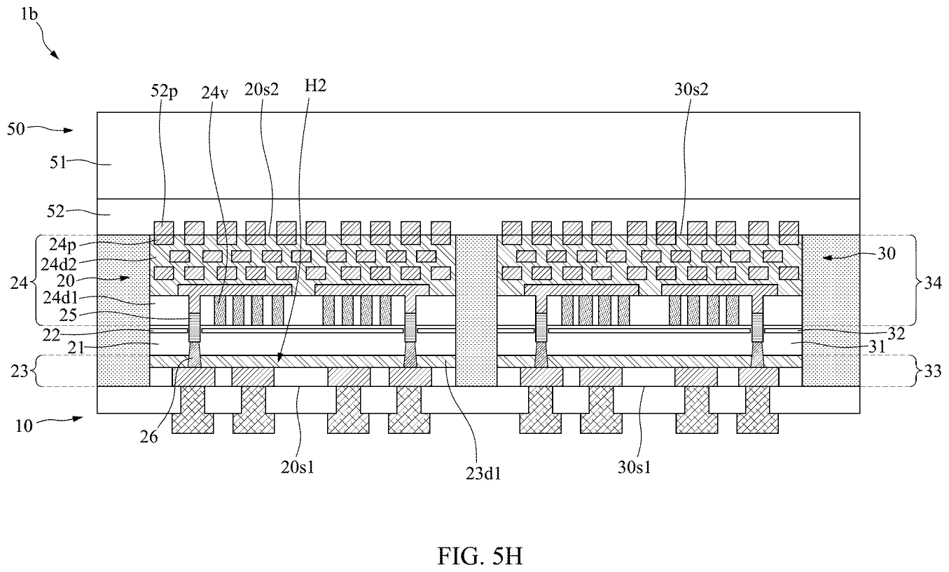

FIG. 5A, FIG. 5B, FIG. 5C, FIG. 5D, FIG. 5E, FIG. 5F, FIG. 5G and FIG. 5H illustrate one or more stages of an example of a method for manufacturing an electronic device according to some embodiments of the present disclosure. The initial stage of the illustrated process is the same as, or similar to, the stage illustrated in FIG. 4A through FIG. 4G. FIG. 5A depicts a stage subsequent to that depicted in FIG. 4G.

Referring to FIG. 5A, a conductive layer 23m1 may be formed on or below the conductive via 26. A dielectric layer 23d2 may be formed on or below the dielectric layer 23d1.

Referring to FIG. 5B, a carrier 75 may be provided. The carrier 75 may include, for example, a silicon carrier, a glass carrier, or other suitable carriers. A conductive layer 23m2 and a dielectric layer 23d3 may be formed over a surface (e.g., an upper surface) of the carrier 75.

Referring to FIG. 5C, the carrier 75 may be bonded to the redistribution structure 23 to form a hybrid-bonding structure H2 at the interface between the redistribution structure 23 and the carrier 75. For example, the conductive layer 23m1 may be bonded to the conductive layer 23m2, and the dielectric layer 23d2 may be bonded to the dielectric layer 23d3. In some embodiments, when the conductive layer 23m1 is partially misaligned with the conductive layer 23m2, the structure as shown in FIG. 2B may be produced.

Referring to FIG. 5D, the units 21u may be separated to produce multiple electronic components 20. Further, the carrier 75 may be sawed and then separated into multiple segments.

Referring to FIG. 5E, an electronic component 30 and a reinforcement component 50 may be provided. The reinforcement component 50 may be bonded or attached to the redistribution structure 24 by, for example, a hybrid-bonding technique or other suitable techniques. The electronic component 30 may be bonded or attached to the reinforcement component 50. The processes of singulation of the electronic component 30 may be the same as or similar to those described in FIG. 5A to FIG. 5D. The conductive elements 52p of the redistribution structure 52 may be bonded to conductive elements 24p of the redistribution structure 24, and the dielectric material of the redistribution structure 52 may be bonded to the dielectric layer 24d2 of the redistribution structure 24. Similarly, the reinforcement component 50 may be bonded or attached to the electronic component 30 by, for example, a hybrid-bonding technique or other suitable techniques. In some embodiments, the bonding between the redistribution structure 52 and the redistribution structure 24 may involve a copper to copper bonding.

Referring to FIG. 5F, an encapsulant 40 may be formed. The encapsulant 40 may encapsulate the electronic components 20 and 30. The encapsulant 40 may cover the surface 20s1 of the electronic component 20 and the surface 30s1 of the electronic component 30.

Referring to FIG. 5G, the encapsulant 40 may be ground. Further, the carriers (e.g., carrier 75) may be removed by a grinding technique. The hybrid-bonding structure H2 may be exposed by the encapsulant 40.

Referring to FIG. 5H, a circuit structure 10 may be formed on or below the redistribution structure 23. As a result, an electronic device (e.g., the electronic device 1b as shown in FIG. 2A) may be produced. In this embodiment, multiple carriers (e.g., carrier 75) may be removed simultaneously by a grinding technique, which improves the cycle time of a manufacturing procedure.

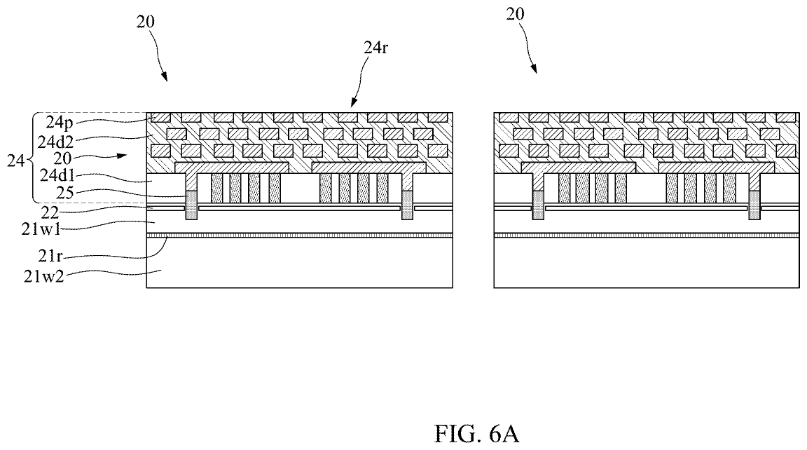

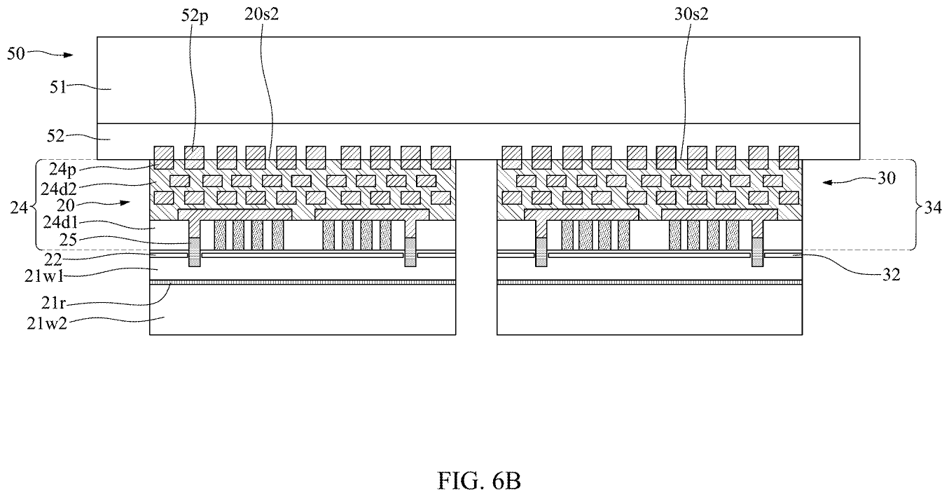

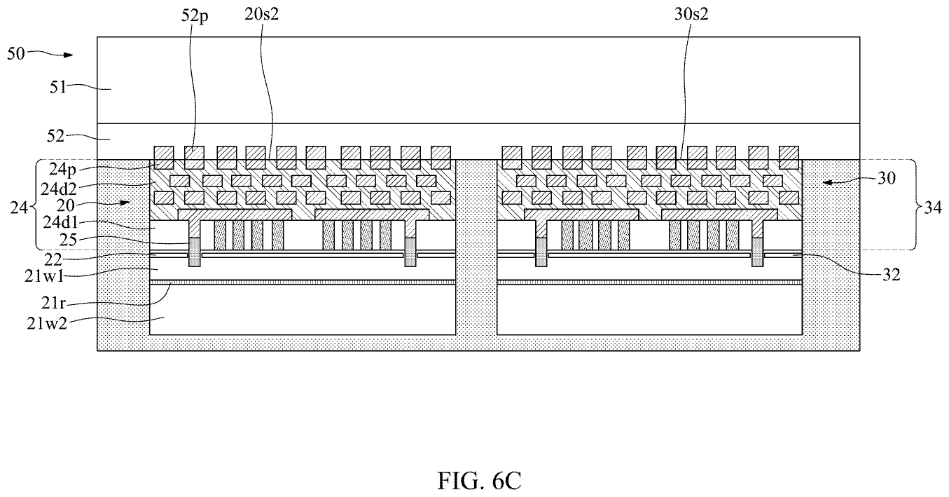

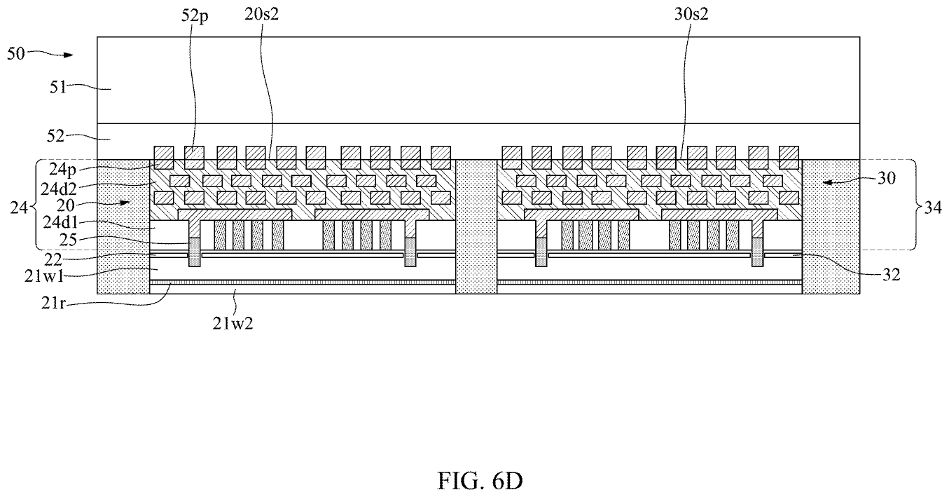

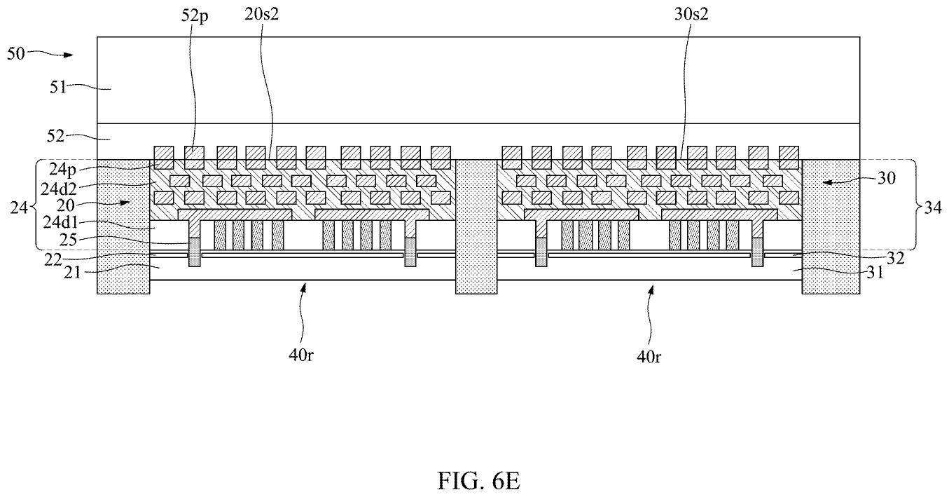

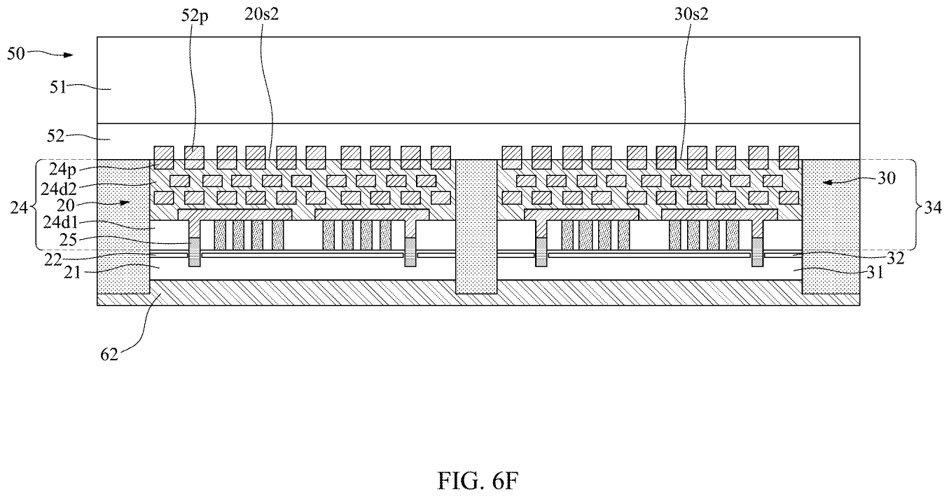

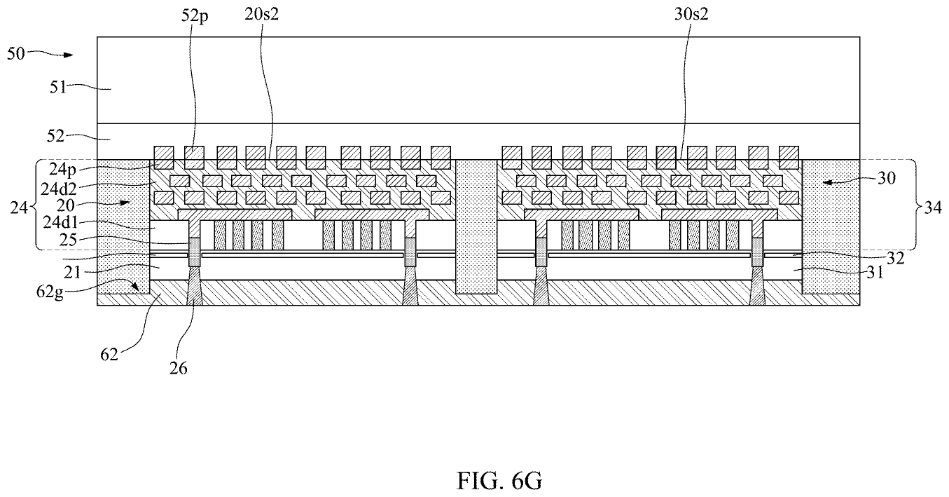

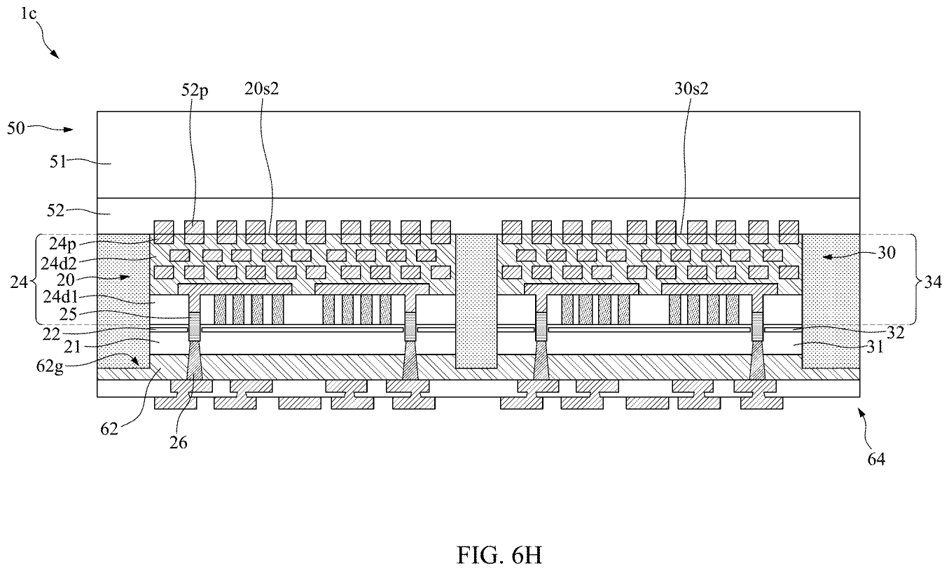

FIG. 6A, FIG. 6B, FIG. 6C, FIG. 6D, FIG. 6E, FIG. 6F, FIG. 6G, and FIG. 6H illustrate one or more stages of an example of a method for manufacturing an electronic device according to some embodiments of the present disclosure. The initial stage of the illustrated process is the same as, or similar to, the stage illustrated in FIG. 4A through FIG. 4B. FIG. 6A depicts a stage subsequent to that depicted in FIG. 4B.

Referring to FIG. 6A, the units 21u as shown in FIG. 4B may be separated, which may result in the production of multiple electronic components 20.

Referring to FIG. 6B, an electronic component 30 and a reinforcement component 50 may be provided. The reinforcement component 50 may be bonded or attached to the redistribution structure 24 by, for example, a hybrid-bonding technique or other suitable techniques. The electronic component 30 may be bonded or attached to the reinforcement component 50. For example, the conductive elements 52p of the redistribution structure 52 may be bonded to conductive elements 24p of the redistribution structure 24, and the dielectric material of the redistribution structure 52 may be bonded to the dielectric layer 24d2 of the redistribution structure 24. Similarly, the reinforcement component 50 may be bonded or attached to the electronic component 30 by, for example, a hybrid-bonding technique or other suitable techniques. In some embodiments, the bonding between the redistribution structure 52 and the redistribution structure 24 may involve a copper to copper bonding.

Referring to FIG. 6C, an encapsulant 40 may be formed. The encapsulant 40 may encapsulate the electronic components 20 and 30.

Referring to FIG. 6D, the encapsulant 40 may be ground. The portion 21w2 of the base 21 may be ground so that the thickness of the portion 21w2 may be reduced. The portion 21w2 may be exposed by the encapsulant 40.

Referring to FIG. 6E, the releasing part 21r and the portion 21w2 may be removed. A portion of the base (not annotated) of the electronic component 30 may be removed. Recesses 40r may be formed to expose the electronic components 20 and 30.

Referring to FIG. 6F, a planarization layer 62 may be formed to fill the recess 40r as shown in FIG. 6E. The planarization layer 62 may cover the electronic components 20 and 30 and the encapsulant 40.

Referring to FIG. 6G, a conductive via 26 may be formed to penetrate the planarization layer 62 and a portion of the base 21 (or base 31).

Referring to FIG. 6H, a circuit structure 64 may be formed on or below the planarization layer 62. As a result, an electronic device (e.g., the electronic device 1c as shown in FIG. 3A) may be produced. In this embodiment, at least one of the stages, which is related to attaching the electronic component to the second carrier, may be omitted. Thus, the manufacturing process may be simplified.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to +10% of that numerical value, such as less than or equal to +5%, less than or equal to +4%, less than or equal to +3%, less than or equal to +2%, less than or equal to #1%, less than or equal to +0.5%, less than or equal to +0.1%, or less than or equal to +0.05%. For example, two numerical values can be deemed to be “substantially” the same or equal if a difference between the values is less than or equal to +10% of an average of the values, such as less than or equal to +5%, less than or equal to +4%, less than or equal to +3%, less than or equal to +2%, less than or equal to +1%, less than or equal to +0.5%, less than or equal to +0.1%, or less than or equal to +0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a first electronic component with a first technology node; and
a second electronic component with a second technology node different from the first technology node; and
a reinforcing component supporting the first electronic component and the second electronic component,
wherein the first electronic component has an upper surface facing the reinforcing component and a lower surface configured to receive a first power.

2. The electronic device of claim 1, wherein the reinforcing component is electrically connected to the first electronic component and the second electronic component.

3. The electronic device of claim 1, wherein the second electronic component has an upper surface facing the reinforcing component and a lower surface configured to receive a second power different from the first power.

4. The electronic device of claim 1, wherein the reinforcing component includes a data storage component.

5. The electronic device of claim 1, further comprising:
a power delivery circuit connected to a logic region of the first electronic component, wherein the power delivery circuit has a surface defined as a lower surface of the first electronic component.

6. The electronic device of claim 5, wherein the first electronic component comprises a base portion and a conductive via at least partially disposed within the base portion, and the conductive via is electrically connected to the logic region and the power delivery circuit.

7. The electronic device of claim 6, wherein the base portion comprises a silicon portion.

8. The electronic device of claim 5, further comprising:
an encapsulant encapsulating the first electronic component, the power delivery circuit, and
the second electronic component.

9. The electronic device of claim 8, further comprising:
a circuit structure disposed under the encapsulant, the first electronic component, the second electronic component, wherein the circuit structure is configured provide the first electronic component and the second electronic component with a power transmission path.

10. The electronic device of claim 9, wherein the circuit structure provides the first electronic component, the second electronic component, and the reinforcing component with an external non-power transmission path.

11. The electronic device of claim 1, wherein the reinforcing component comprises a conductive element configured to provide the electronic device with an electrical path to an external device.

12. The electronic device of claim 8, further comprising:
a conductive element spaced apart from the first electronic component and the second electronic component, wherein the conductive element passes through the encapsulant and is configured to provide the electronic device with an electrical path to an external device.

13. The electronic device of claim 8, wherein a portion of the encapsulant is disposed under the power delivery circuit.

14. The electronic device of claim 1, further comprising:
an encapsulant encapsulating the first electronic component and the second electronic component, wherein the encapsulant and a lower surface of the first electronic component define a step; and
a planarization layer at least partially disposed on the step and has a planar surface disposed under the first electronic component and the encapsulant.

15. An electronic device, comprising:
a first chiplet;
a second chiplet; and
a data storage component configured to communicate with the first chiplet and the second chiplet,
wherein the first chiplet has an upper surface facing the data storage component and a lower surface configured to receive a power.

16. The electronic device of claim 15, further comprising:
an encapsulant encapsulating the first chiplet and the second chiplet, wherein the encapsulant defines a first recess exposing the first chiplet and a second recess exposing the second chiplet.

17. The electronic device of claim 16, further comprising:
a planarization layer disposed within the first recess and the second recess, wherein a portion of the planarization layer is disposed under the encapsulant.

18. The electronic device of claim 17, further comprising:
a power delivery circuit disposed under the planarization layer and the data storage component; and
a conductive element disposed within the planarization layer and electrically connected to the power delivery circuit and the first chiplet.

19. An electronic device, comprising:
a reinforcement component;
a first electronic component supported by the reinforcement component and having a backside power delivery circuit; and
a second electronic component supported by the reinforcement component and spaced apart from the first electronic component,
wherein an edge of the first electronic component is slanted with respect to an edge of the second electronic component in a bottom view.

20. The electronic device of claim 19, wherein an imaginary line passing through a geometry center of the first electronic component and a geometry center of the second electronic component is slanted with respect to an edge of the reinforcement component.
